(19) United States
(12) Patent Application Publication
(10) Pub. No.: US 2026/0092978 A1
(43) Pub. Date: Apr. 2, 2026

(54) OPEN WIRE FAULT DETECTION AGNOSTIC TO BATTERY CELL CHARACTERISTICS

(71) Applicant: Rivian IP Holdings, LLC, Irvine, CA (US)

(72) Inventors: Tejas Abhay CHAFEKAR, Edwards, IL (US); Kishore Kumar SUKUMAR, San Jose, CA (US); Won Tae JOE, Lake Forest, CA (US); Vasant Kumar EASWARAN, Frisco, TX (US); Robin CHOUDHURY, Irvine, CA (US)

(21) Appl. No.: 19/255,755

(22) Filed: Jun. 30, 2025

Related U.S. Application Data
(60) Provisional application No. 63/701,008, filed on Sep. 30, 2024.

(51) Int. Cl. G01R 31/3835; H01M 10/48; H01M 50/51

(52) U.S. Cl. CPC G01R 31/3835; H01M 10/482; H01M 50/51

(57) ABSTRACT

Aspects of the subject disclosure relate to open wire fault detection agnostic to battery cell characteristics. A system may include an electronic control unit (ECU) and a battery monitoring circuit that generates an open wire ratio value for each battery cell in a battery. The battery monitoring circuit compares the open wire ratio value of each battery cell to a predetermined threshold, in which a first battery cell and a second battery cell have respective open wire ratio values not exceeding the predetermined threshold. The battery monitoring circuit determines whether the second battery cell has a true open wire condition based on a comparison between the open wire ratio value of a third battery cell and the predetermined threshold and sends an indication of an open wire fault detection of one or more battery cells to the ECU to cause a transition of the battery into a safe state.

### CROSS-REFERENCE TO RELATED APPLICATION(S)

This application claims the benefit of U.S. Provisional Application Ser. No. 63/701,008, entitled “OPEN WIRE FAULT DETECTION AGNOSTIC TO BATTERY CELL CHARACTERISTICS,” and filed on Sep. 30, 2024, the disclosure of which is expressly incorporated by reference herein in its entirety.

### INTRODUCTION

Batteries are often used as a source of power, including as a source of power for electric vehicles that include wheels that are driven by an electric motor that receives power from the battery. This application is directed to open wire detection and more particularly, open wire fault detection agnostic to battery cell characteristics.

### SUMMARY

Electric vehicles with large batteries need to ensure safe operation for high-load applications like electronics and motors, necessitating effective open wire detection within the fault tolerant time interval (FTTI). Traditional detection methods rely on voltage measurements, which are influenced by a battery monitoring integrated circuit (BMIC) hardware design. This can lead to inaccuracies when hardware changes, causing potential safety violations. Existing approaches face challenges with varying voltage behaviors across different battery generations and hardware, leading to potential delayed detection of true faults or incorrect identification of open wires as false positives, which can trigger inaccurate safety responses.

Embodiments of the subject technology provide for an open wire detection algorithm that operates independently of battery cell voltage characteristics and hardware design. The open wire detection algorithm assesses the open wire ratios of adjacent strings (N, N+1, and N+2) to determine if a string is truly open, minimizing false detections. In one or more other implementations, physical separation by a busbar may affect detection accuracy. The open wire detection algorithm may conservatively estimate the state of strings near a busbar to avoid overreaction in the safety responses.

In accordance with one or more aspects of the disclosure, a battery management system is provided that includes an electronic control unit (ECU) and a battery monitoring circuit configured to determine an open wire ratio value for each battery cell of a plurality of battery cells in a battery; determine that a first battery cell and a second battery cell of the plurality of battery cells have potential open wire conditions based on a comparison between the open wire ratio value of each of the first battery cell and the second battery cell and a predetermined threshold, in which the open wire ratio value not exceeding the predetermined threshold indicates a potential open wire condition; determine whether the potential open wire condition associated with the second battery cell corresponds to a true open wire fault detection based on a comparison between the open wire ratio value of a third battery cell of the plurality of battery cells and the predetermined threshold; and send an indication of which of the plurality of battery cells is associated with a true open wire fault detection to the ECU to cause a transition of the battery into a safe state.

In accordance with one or more aspects of the disclosure, a method includes determining an open wire ratio value for each battery cell of a plurality of battery cells in a battery; comparing the open wire ratio value of each battery cell of the plurality of battery cells to a predetermined threshold, wherein a first battery cell and a second battery cell of the plurality of battery cells have respective open wire ratio values that do not exceed the predetermined threshold; determining whether the second battery cell has a true open wire condition based on a comparison between the open wire ratio value of a third battery cell of the plurality of battery cells and the predetermined threshold; and sending, to an electronic control unit of a vehicle, an indication of whether one or more battery cells of the plurality of battery cells is associated with an open wire fault detection to cause a transition of the battery into a safe state.

In accordance with one or more aspects of the disclosure, a vehicle including one or more sensors; an electronic control unit (ECU); and a battery monitoring circuit configured to determine an open wire ratio value for each battery cell of a plurality of battery cells in a battery; determine that a first battery cell and a second battery cell of the plurality of battery cells have potential open wire conditions based on the open wire ratio value of each of the first battery cell and the second battery cell not exceeding a predetermined threshold; compare the open wire ratio value of a third battery cell of the plurality of battery cells to the predetermined threshold to determine whether the second battery cell has a true open wire condition; and send an indication of an open wire fault detection associated with one or more battery cells of the plurality of battery cells to the ECU to cause a transition of the battery into a safe state.

### BRIEF DESCRIPTION OF THE DRAWINGS

Certain features of the subject technology are set forth in the appended claims. However, for purpose of explanation, several embodiments of the subject technology are set forth in the following figures.

FIG. 1A and FIG. 1B illustrate schematic perspective side views of example implementations of a vehicle having a battery pack, in accordance with aspects of the present disclosure.

FIG. 2 illustrates a schematic perspective side view of another example implementation of a vehicle having a battery pack, in accordance with aspects of the present disclosure.

FIG. 3 illustrates a block diagram of an example vehicle for open wire fault detection in accordance with one or more implementations of the subject technology.

FIG. 4 illustrates a block diagram of an example battery monitoring circuitry in accordance with one or more implementations of the subject technology.

FIGS. 5A and 5B illustrate schematic diagrams of an example battery monitoring circuitry in accordance with one or more implementations of the subject technology.

FIGS. 6A-6C illustrate block diagrams of an example process for open wire fault detection in accordance with one or more implementations of the subject technology.

FIG. 7 illustrates a flow diagram of an example process for performing open wire fault detection in accordance with one or more implementations of the subject technology.

FIG. 8 illustrates an electronic system with which one or more implementations of the subject technology may be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form to avoid obscuring the concepts of the subject technology.

In one or more implementations, electric vehicles utilize large batteries capable of driving various high-load applications, including automotive electronics, motors, drivetrains, heat pumps, and heating, ventilation and air conditioning (HVAC) systems, which require significant current. For applications requiring high automotive safety integrity level (ASIL), diagnosing open wires between the battery cells and the monitoring circuit within the fault tolerant time interval (FTTI) is imperative to facilitate a transition to a safe state.

Traditional open wire detection algorithms are based on voltage measurements taken at different time intervals, both with and without a pull-up or pull-down circuit. Some approaches rely on the characteristic voltage behavior of battery cells with open wires to detect and differentiate between an open wire fault and a true over-voltage or under-voltage condition. The voltage behavior, which reflects fluctuations when cell strings are open, can be heavily influenced by the design of the BMIC hardware. Therefore, detection logic would need to be adjusted with each hardware change. The application of an unmodified open wire detection algorithm across different hardware designs may result in false positives or delayed detection of true positives, potentially violating the FTTI requirements for vehicle safety.

In one or more implementations, true open wire conditions of a cell string may exhibit different behaviors between different generations of battery cells and hardware. In some prior approaches, if the high-side of an odd-numbered cell became open, the voltages of both the affected odd cell and the adjacent (or neighboring) even cell would fluctuate beyond their over/under voltage thresholds and remain above these thresholds. Conversely, if the high-side of an even-numbered cell became open, the cell voltage would decay to zero. In one or more other implementations, in the battery monitoring integrated circuit (IC) hardware of some other approaches, the voltage fluctuations of cells, whether even or odd, do not always exceed the over/under voltage thresholds and may return within the operating range.

These behaviors can lead to two primary issues: a) delayed detection of true open wires, which can result in violations of the FTTI, and b) false detection of wires that are not open. The system's reaction may differ when one cell string is open compared to when multiple cell strings are open. Multiple open cell strings can trigger a more extreme safe state reaction, leading to a loss of propulsion, whereas a single open string allows continued driving with limited performance. If only one string is open, false detection of a second open string may trigger a more significant safe state reaction. Additionally, delayed detection of an open string may compromise the safety concept. Therefore, reliable detection of multiple open strings is desirable to prevent unintentional loss of propulsion.

The subject technology provides for the open wire detection algorithm to be agnostic to the voltage characteristics of true open wires, allowing the same algorithm to be applied across multiple programs with different cell chemistries. To determine whether each string, denoted as string N, is open, the open wire detection algorithm can evaluate the open wire ratios of strings N, N+1, and N+2. If the ratio for string N falls below the open wire threshold, string N is identified as open.

The open state of string N affects the open wire ratio of the adjacent string, N+1. To avoid incorrectly detecting string N+1 as open, the open wire detection algorithm checks the pen wire ratio of string N+2. If the ratio for string N+2 remains within the normal range (or greater than the open wire threshold), it is concluded that string N+2 is not influenced by string N+1, and thus, string N+1 is not considered open. The open wire detection algorithm processes all strings sequentially using a loop, with the last two strings handled separately since there are no N+2 strings in those cases. This approach prevents the false detection of string N+1 as open and facilitates accurate open wire counts, maintaining a count of one for string N instead of incorrectly counting both strings N and N+1, thereby preventing an overreaction as previously identified.

In one or more other implementations, if string N is truly open and a busbar separates strings N+1 and N+2, the behavior of string N+2's open wire ratio may not be used to determine the state of string N+1 due to the physical separation by the busbar. As a result, the open wire detection algorithm may not detect the state of string N+1 thus estimating that string N+1 as truly open. This conservative estimation can only lead to an overreaction if only one string, adjacent to the string immediately before a busbar, is truly open.

In one or more implementations, the term “string” refers to a series of battery cells and can be used interchangeably with the term “cell” when discussing battery configurations. This can apply to use cases where multiple battery cells are connected in series to form a string, and this terminology remains consistent throughout.

The subject technology differentiates itself from existing approaches by making the open wire detection algorithm independent of the battery monitoring IC hardware design. The competitive advantages of the subject technology include compatibility with various cell chemistries and robust detection of open wires in battery cells, which enhances overall battery safety. By making the open wire detection algorithm agnostic to both hardware and cell chemistry, the subject technology supports scalability and reduces development time for multiple programs. Additionally, the subject technology leads to more reliable open wire detection, further improving battery safety.

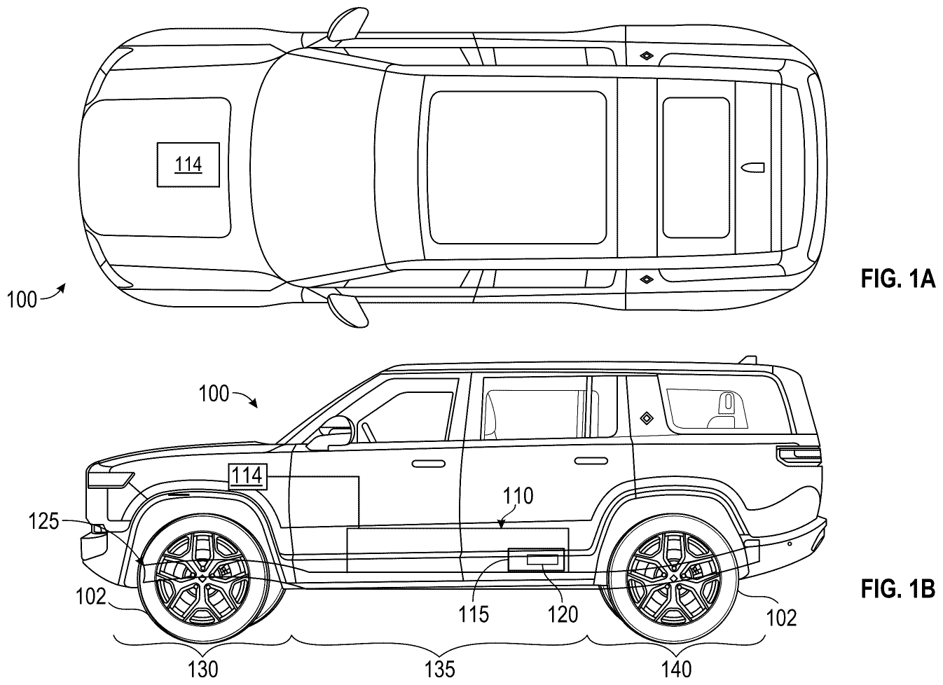

FIG. 1A is a diagram illustrating an example implementation of a moveable apparatus as described herein. In the example of FIG. 1A, a moveable apparatus is implemented as a vehicle 100. As shown, the vehicle 100 may include one or more battery packs, such as battery pack 110. The battery pack 110 may be coupled to one or more electrical systems of the vehicle 100 to provide power to the electrical systems.

In one or more implementations, the vehicle 100 may be an electric vehicle having one or more electric motors that drive wheels 102 of the vehicle 100 using electric power from the battery pack 110. In one or more implementations, the vehicle 100 may also, or alternatively, include one or more chemically powered engines, such as a gas-powered engine or a fuel cell powered motor. For example, electric vehicles can be fully electric or partially electric (e.g., hybrid or plug-in hybrid). In various implementations, the vehicle 100 may be a fully autonomous vehicle that can navigate roadways without a human operator or driver, a partially autonomous vehicle that can navigate some roadways without a human operator or driver or that can navigate roadways with the supervision of a human operator, may be an unmanned vehicle that can navigate roadways or other pathways without any human occupants, or may be a human operated (non-autonomous) vehicle configured for a human operator.

In the example of FIG. 1A, the vehicle 100 is implemented as a sport utility vehicle (e.g., an electric sport utility vehicle) having a battery pack 110. As shown, the battery pack 110 may include one or more battery modules 115, which may include one or more battery cells 120. As shown in FIG. 1A, the battery pack 110 may also, or alternatively, include one or more battery cells 120 mounted directly in the battery pack 110 (e.g., in a cell-to-pack configuration). In one or more implementations, the battery pack 110 may be provided without any battery modules 115 and with the battery cells 120 mounted directly in the battery pack 110 (e.g., in a cell-to-pack configuration) and/or in other battery units that are installed in the battery pack 110. A vehicle battery pack can include multiple energy storage devices that can be arranged into such as battery modules or battery units. A battery unit or module can include an assembly of cells that can be combined with other elements (e.g., structural frame, thermal management devices) that can protect the assembly of cells from heat, shock and/or vibrations.

For example, the battery cell 120 can be included in a battery, a battery unit, a battery module and/or a battery pack to power components of the vehicle 100. For example, a battery cell housing of the battery cell 120 can be disposed in the battery module 115, the battery pack 110, a battery array, or other battery unit installed in the vehicle 100.

In some implementations, the battery pack 110 can be combined with a battery management device 114 that can determine an open wire ratio value for each battery cell (e.g., battery cell 120) of a plurality of battery cells in a battery (e.g., battery pack 110). The battery management device 114 can determine that a first battery cell and a second battery cell of the plurality of battery cells have potential open wire conditions based on a comparison between the open wire ratio value of each battery cell of the plurality of battery cells and a predetermined threshold. In one or more implementations, an open wire ratio value not exceeding the predetermined threshold indicates a potential open wire condition. The battery management device 114 can determine whether the potential open wire condition associated with the second battery cell corresponds to a true open wire fault detection based on a comparison between the open wire ratio value of a third battery cell of the plurality of battery cells and the predetermined threshold. The battery management device 114 can send an indication of which of the plurality of battery cells is associated with a true open wire fault detection to an electronic control unit of the vehicle 100 to cause a transition of the battery pack 110 and/or the vehicle 100 into a safe state.

As discussed in further detail hereinafter, the battery cells 120 may be provided with a battery cell housing that can be provided with any of various outer shapes. The battery cell housing may be a rigid housing in some implementations (e.g., for cylindrical or prismatic battery cells). The battery cell housing may also, or alternatively, be formed as a pouch or other flexible or malleable housing for the battery cell in some implementations. In various other implementations, the battery cell housing can be provided with any other suitable outer shape, such as a triangular outer shape, a square outer shape, a rectangular outer shape, a pentagonal outer shape, a hexagonal outer shape, or any other suitable outer shape. In some implementations, the battery pack 110 may not include modules (e.g., the battery pack may be module-free). For example, the battery pack 110 can have a module-free or cell-to-pack configuration in which the battery cells 120 are arranged directly into the battery pack 110 without assembly into a battery module 115. In one or more implementations, the vehicle 100 may include one or more busbars, electrical connectors, or other charge collecting, current collecting, and/or coupling components to provide electrical power from the battery pack 110 to various systems or components of the vehicle 100. In one or more implementations, the vehicle 100 may include control circuitry such as a power stage circuit that can be used to convert DC power from the battery pack 110 into AC power for one or more components and/or systems of the vehicle (e.g., including one or more power outlets of the vehicle and/or the motor(s) that drive the wheels 102 of the vehicle). The power stage circuit can be provided as part of the battery pack 110 or separately from the battery pack 110 within the vehicle 100.

The example of FIG. 1A in which the vehicle 100 is implemented as a sport utility vehicle is merely illustrative. In one or more other implementations, the vehicle 100 including the battery pack 110 may be implemented as a truck (e.g., an electric pickup truck). The vehicle 100 including the battery pack 110 may include a cargo storage area that is enclosed within the vehicle 100 (e.g., behind a row of seats within a cabin of the vehicle). In other implementations, the vehicle 100 may be implemented as another type of electric truck, an electric delivery van, an electric automobile, an electric car, an electric motorcycle, an electric scooter, an electric bicycle, an electric passenger vehicle, an electric passenger or commercial truck, a hybrid vehicle, an aircraft, a watercraft, and/or any other movable apparatus having a battery pack 110 (e.g., a battery pack or other battery unit that powers the propulsion or drive components of the moveable apparatus).

As shown in FIG. 1B, vehicle 100 may include a support structure such as a chassis 125 (e.g., a frame, internal frame, or other support structure). The chassis 125 may support various components of the vehicle 100. As shown, the chassis 125 may span a front portion 130 (e.g., a hood or bonnet portion), center body portion 135, and a rear portion 140 (e.g., a trunk, payload, or boot portion) of the vehicle 100 in some implementations. In one or more implementations, battery pack 110 may be installed on the chassis 125 (e.g., within one or more of the front portions 130, center body portion 135, or the rear portion 140). In one or more other implementations, battery pack 110 may include or be electrically coupled with one or more one busbars (e.g., one or more current collector elements), of which may include electrically conductive material to connect or otherwise electrically couple battery module(s) 115 or the battery cell(s) 120 with other electrical components of vehicle 100 to provide electrical power to various systems or components of vehicle 100.

In the example of FIG. 1B, the vehicle 100 may include a cargo storage area that is enclosed within the vehicle 100 (e.g., behind a row of seats within a cabin of the vehicle 100). In other implementations, the vehicle 100 may be implemented as an electric truck, another type of electric SUV, an electric delivery van, an electric automobile, an electric car, an electric motorcycle, an electric scooter, an electric bicycle, an electric passenger vehicle, an electric passenger or commercial truck, a hybrid vehicle, an aircraft, a watercraft, and/or any other movable apparatus having a battery pack 110 (e.g., a battery pack or other battery unit that powers the propulsion or drive components of the moveable apparatus).

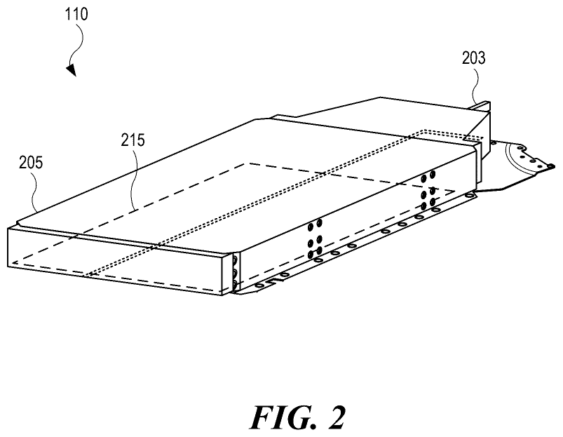

FIG. 2 depicts an example battery pack 110. Battery pack 110 may include multiple battery cells 120 (e.g., directly installed within the battery pack 110, or within batteries, battery units, and/or battery modules 115 as described herein) and/or battery modules 115, and one or more conductive coupling elements for coupling a voltage generated by the battery cells 120 to a power-consuming component, such as the vehicle 100 and/or an electrical system of a building 180. For example, the conductive coupling elements may include internal connectors and/or contactors that couple together multiple battery cells 120, battery units, batteries, and/or multiple battery modules 115 within the battery pack frame 205 to generate a desired output voltage for the battery pack 110. The battery pack 110 may also include one or more external connection ports. As shown, the battery pack 110 may include an electrical contact 203 (e.g., a high voltage connector) by which an external load (e.g., the vehicle 100) may be electrically coupled to the battery modules and/or battery cells in the battery pack 110. For example, an electrical cable (e.g., cable/connector 106) may be connected between the electrical contact 203 and an electrical system of the vehicle 100 or a building (not shown), to provide electrical power to the vehicle 100 or the building. In some aspects, the battery pack 110 may be connected to the battery management device 114 via the electrical contact 203.

As shown, the battery pack 110 may include a battery pack frame 205 (e.g., a battery pack housing or pack frame). For example, the battery pack frame 205 may house or enclose one or more battery modules 115 and/or one or more battery cells 120, and/or other battery pack components. In one or more implementations, the battery pack frame 205 may include or form a shielding structure on an outer surface thereof (e.g., a bottom thereof and/or underneath one or more battery module 115, battery units, batteries, and/or battery cells 120) to protect the battery module 115, battery units, batteries, and/or battery cells 120 from external conditions (e.g., if the battery pack 110 is installed in a vehicle 100 and the vehicle 100 is driven over rough terrain, such as off-road terrain, trenches, rocks, rivers, streams, etc.).

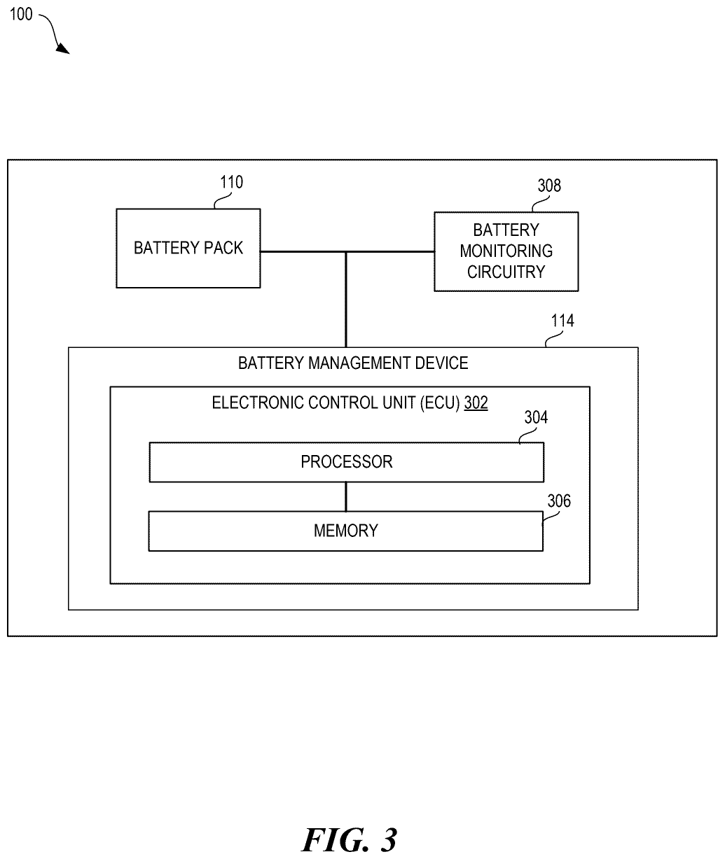

FIG. 3 illustrates a block diagram of an example vehicle 100 for open wire fault detection in accordance with one or more implementations of the subject technology. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

The vehicle 100 may include the battery pack 110, the battery management device 114 and battery monitoring circuitry 308. The battery management device 114 may include one or more electronic control units (ECUs) 302. The ECU 302 may include a processor 304 and a memory 306. In one or more implementations, the vehicle 100 may include a processor 304 and/or a memory 306 separate from the ECU 302. For example, the vehicle 100 may not include the ECU 302 and may include the processor 304 as a part or all of a separate semiconductor device. In one or more implementations, vehicle 100 may include multiple ECUs 302 that each control particular functionality of the vehicle 100.

The processor 304 may include suitable logic, circuitry, and/or code that enables processing data and/or controlling operations of the vehicle 100. In this regard, the processor 304 may be enabled to provide control signals to various other components of the vehicle 100, such as for example, the battery management device 114. For example, the battery management device 114 may receive a signal from the ECU 302 (e.g., from the processor 304 of the ECU 302), such as a signal to trigger open wire fault detections on the battery pack 110. The processor 304 may also control transfers of data between various portions of the vehicle 100. The processor 304 may further implement an operating system, such as a real-time operating system, or may otherwise execute code to manage operations of the vehicle 100.

The memory 306 may include suitable logic, circuitry, and/or code that enable storage of various types of information such as received data, machine learning model data, user authentication data, and/or configuration information. The memory 306 may include, for example, random access memory (RAM), read-only memory (ROM), flash, and/or magnetic storage. In one or more implementations, the memory 306 may store identifiers and/or authentication information of one or more users to determine authorized users and/or authorized authentication devices of the vehicle 100. The memory 306 may also store account information corresponding to an authorized user for exchanging information between the vehicle 100 and a remote server. The memory 306 may also store location data, including the geographic locations of historical route projections. The memory 306 may also store measurement data relating to instances of open wire fault detections performed on the battery pack 110. The memory 306 may also store battery data, including an amount of time that has elapsed since the battery was last charged.

In one or more implementations, one or more of the processor 304, the memory 306, the battery pack 110, the battery management device 114, the data sources 308, the ECU 302, and/or one or more portions thereof, may be implemented in software (e.g., subroutines and code), may be implemented in hardware (e.g., an Application Specific Integrated Circuit (ASIC), a Field Programmable Gate Array (FPGA), a Programmable Logic Device (PLD), a controller, a state machine, gated logic, discrete hardware components, or any other suitable devices), and/or a combination of both.

In one or more implementations, potential failure modes exist where a breakage may occur at any point in the battery pack 110, such as in the wiring harness, printed circuit board (PCB) traces, or within the integrated circuit (IC). Such a failure can result in an inability to sense a battery cell voltage. This specific failure mode can be referred to as “open wire.” An open wire may occur when the voltage-sensing wire becomes disconnected at an unspecified location within the battery pack 110. Software may be utilized to detect this disconnection and cause a reaction in the battery pack 110 accordingly. If one or more battery cells 120 become disconnected or wires break beyond a certain threshold, the battery management device 114 may not be able to accurately estimate the state of the battery pack 110, potentially leading to safety concerns, range estimation issues, and a compromised user experience.

In one or more implementations, the battery management device 114 may react to breakages based on the number of open wires detected. For example, if the battery pack 110 contains 26 cells or 108 cells, depending on the configuration, the reaction (or transition to a safe state level) may vary based on the number of disconnections. With a single breakage, the battery management device 114 allows the vehicle 100 to operate in a limited power or energy mode, enabling the user of the vehicle 100 to drive to a service station but with reduced acceleration and range compared to normal operation. In the case of multiple breakages, the battery management device 114 can respond more severely by preventing the vehicle 100 from operating, initiating a controlled shutdown, and requiring the vehicle 100 to be towed to a service center for repairs.

In one or more implementations, detection of whether there are breakages (open wires) in the battery pack 110 is imperative and, if so, whether the breakages involve a single or multiple open wires. The level of response by the battery management device 114 to the user of the vehicle 100, including the user experience and the operational state of the vehicle 100, can vary depending on the number of open wires detected.

In one or more implementations, when a battery cell 120 experiences a breakage, it can result in specific voltage behavior. For example, if a first cell in a series of connected cells fails, the voltage of that cell may drop below a threshold (e.g., 1.8 volts), which may be the defined under-voltage limit. In one or more other implementations, the voltage of an adjacent cell (e.g., adjacent to the first cell) can rise above the over-voltage threshold (e.g., 4.2 volts). If the voltage of the adjacent cell remains elevated, the battery management device 114 may infer that the previous cell had an open circuit, allowing the battery management device 114 to ignore the over-voltage signal and prevent further diagnostic complications. The open wire detection algorithm may prevent overreacting to false over-voltage readings, which would otherwise trigger a more severe system response.

In one or more implementations, a failure mode detection may be imperative to reduce the occurrences of unnecessary reactions. For example, a single open wire may allow the vehicle 100 to operate in a limited power mode, but a true over-voltage condition can force the battery management device 114 to disconnect the battery pack 110 and shut down the vehicle 100. In one or more other implementations, the open wire detection algorithm may have limitations in detecting open wire conditions with a change in hardware configurations, cell chemistries, and voltage characteristics. For example, instead of measuring cells that remain in a static under- or over-voltage state, the affected cells may exhibit oscillating voltage patterns, moving in and out of their operating ranges. In one or more implementations, this inconsistency in voltage behavior may pose a growing challenge for traditional open wire detection algorithms, impacting their reliance on consistent voltage readings to determine if a cell is faulty. The fluctuating nature of the cell voltage, both in the failing cell and its adjacent cell, may cause a traditional open wire detection algorithm to detect a false positive condition because the traditional open wire detection algorithm may not determine a clear fault condition. Given these new challenges, the traditional open wire detection algorithm may not be adaptable to varying voltage patterns that result from changes in cell chemistry or hardware design.

Embodiments of the subject technology provide for an open wire detection algorithm that is hardware-agnostic to the specific voltage characteristics of the battery pack 110. The open wire detection algorithm of the subject technology allows for consistent performance across different hardware configurations and voltage characteristics, reducing the need for custom algorithms for each program or hardware revision.

In one or more implementations, the battery management device 114 can determine an open wire ratio value for each battery cell (e.g., battery cell 120) of a plurality of battery cells in a battery (e.g., battery pack 110). The battery management device 114 can determine that a first battery cell and a second battery cell of the plurality of battery cells have potential open wire conditions based on a comparison between the open wire ratio value of each battery cell of the plurality of battery cells and a predetermined threshold. In one or more implementations, an open wire ratio value not exceeding the predetermined threshold indicates a potential open wire condition. The battery management device 114 can determine whether the potential open wire condition associated with the second battery cell corresponds to a true open wire fault detection based on a comparison between the open wire ratio value of a third battery cell of the plurality of battery cells and the predetermined threshold. The battery management device 114 can send an indication of which of the plurality of battery cells is associated with a true open wire fault detection to the ECU 302 to cause a transition of the battery pack 110 and/or the vehicle 100 into a safe state.

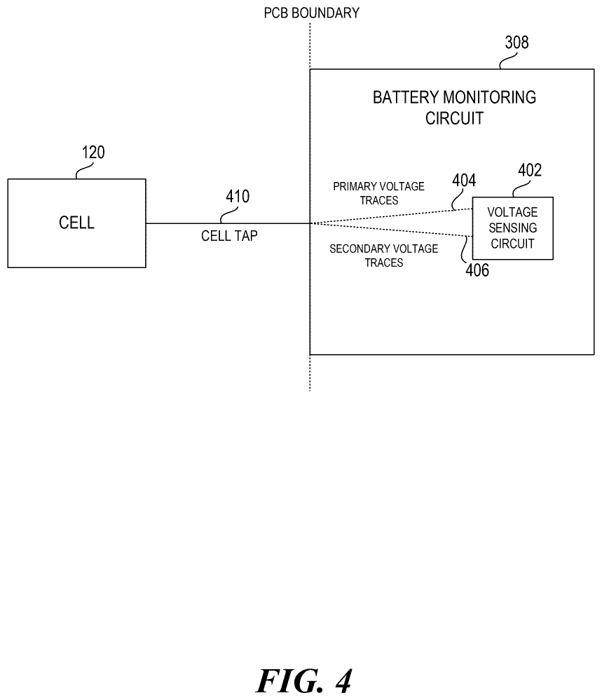

FIG. 4 illustrates a block diagram of an example battery monitoring circuitry in accordance with one or more implementations of the subject technology. In one or more implementations, the battery management device 114 may monitor the state of a cell (e.g., battery cell 120) by having the battery cell 120 connected to a voltage sensing circuit 402, where the voltage sensing circuit 402 may include an ASIC responsible for performing diagnostic measurements. The battery monitoring circuitry 308 also includes cell connectors (referred to as cell taps) for various battery cells 120 in the battery pack 110. For example, a physical wire (e.g., cell tap 410) connects the battery cell 120 to the battery monitoring circuitry 308, which hosts the voltage sensing circuit 402. The battery monitoring circuitry 308 includes a PCB that includes primary voltage traces 404 and secondary voltage traces 406 that electrically connect the battery cell 120 to the voltage sensing circuit 402. The battery monitoring circuitry 308 can monitor the voltage of individual battery cells 120.

In one or more implementations, the voltage sensor circuit 402 may include two redundant measurement pins (e.g., primary measurement pin and secondary measurement pin), which can measure the voltage of the same cell using two distinct methods. For example, if a primary measurement pin reports a cell voltage of 3.6 volts, the secondary measurement pin may report the same value. This redundancy facilitates reliability and safety. In one or more implementations, these redundant measurements are conducted beyond the boundary of the PCB (or the battery monitoring circuitry 308). In one or more implementations, a single wire (e.g., the cell tap 410) connects the battery cell 120 to the voltage sensing circuit 402; however, at the PCB boundary, the single tap 410 splits into two separate traces, namely the primary voltage traces 404 and secondary voltage traces 406. The primary measurement pin may connect to one trace and the secondary measurement pin may connect to the other trace, forming two independent paths to the voltage sensing circuit 402, which reads the battery cell 120 voltage. For each cell in the battery pack 110, voltage characteristics can be continuously monitored. The voltage sensing circuit 402 can read the voltage of up to 16 cells, with the battery monitoring circuitry 308 monitoring their voltage levels for safety and operational purposes. In one or more implementations, a failure mode in the battery pack 110 can be detected when the voltage sensing circuit 402 experiences issues.

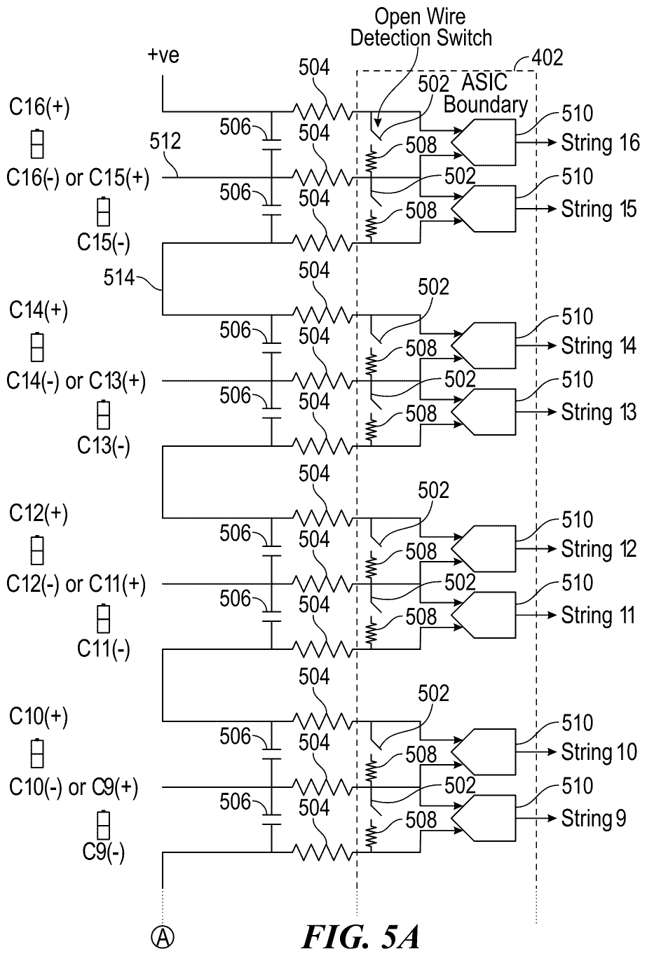

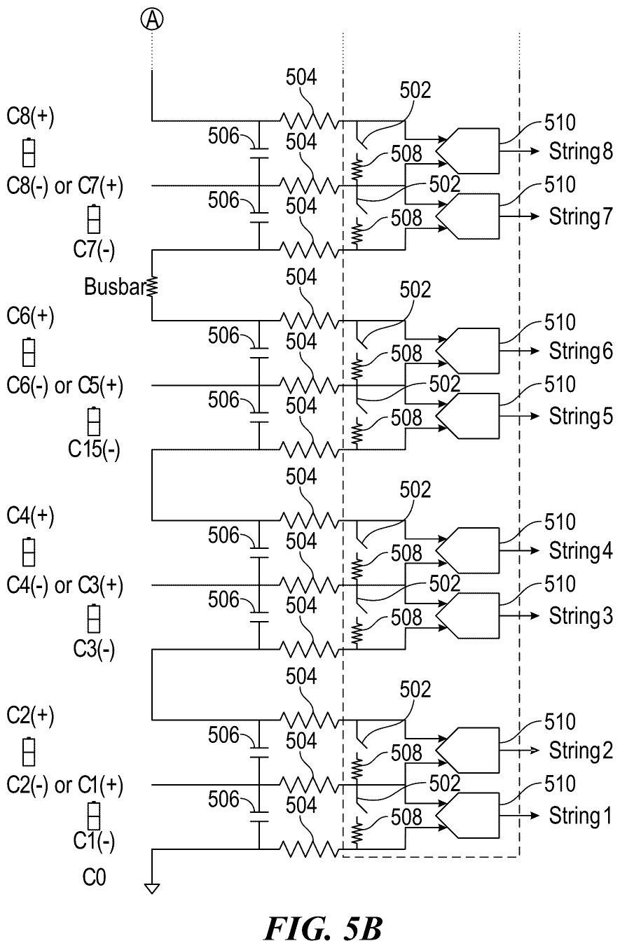

FIGS. 5A and 5B illustrate schematic diagrams of an example battery monitoring circuitry in accordance with one or more implementations of the subject technology. In one or more implementations, each string in the battery pack 110 may have a positive terminal (+) and a negative terminal (−), with adjacent strings sharing common wires. For example, the negative terminal of string 16 may connect to the positive terminal of string 15 at node 512, and the negative terminal of string 15 may connect to the positive terminal of string 14 at node 514, and so on.

When the battery pack 110 interacts with the voltage sensing circuit 402, an open wire detection switch 502 and a resistor 508 are involved. This configuration is connected to an analog-to-digital converter (ADC) 510, which is used for computation purposes. In one or more implementations, a resistor 504 may serve as the input impedance of the ADC 510. Under normal conditions when the open wire detection switch 502 is open, current flows through this path, and the voltage across the resistor 504 is measured by the ADC 510. Capacitors 506 may be arranged between each measurement channel (e.g., across the positive terminal of a first string and the negative terminal of a second string adjacent to the first string).

In one or more implementations, when the open wire detection switch 502 is open, the charge distribution flows through the capacitors 506, affecting the voltage measurements of connected strings. In one or more other implementations, when the open wire detection switch 502 is closed, most of the current bypasses the input impedance of the ADC and flows through the open wire detection switch 502, resulting in a very small current flowing through the resistor 504. Consequently, the voltage measured across the input resistance of the ADC (e.g., the voltage across the resistor 504) becomes very small. In this regard, the battery cell 120 is shorted with the resistor 508 that has a much lower resistance compared to the input resistance of the ADS (or the resistor 504).

In one or more implementations, the open wire detection algorithm may consider the charge distribution between connected strings. As more strings open (e.g., open wire detection switch 502 is open across each measurement channel), the battery monitoring circuitry 308 determines a lower open wire ratio value (e.g., below 0.7) due to this redistribution of charge across the measurement channels. If the open wire detection switch 502 was not open, the charge would return directly to the originating cell, unaffected by other strings. This phenomenon facilitates that open-wire conditions can be detected across the measurement channels of the battery monitoring circuitry 308 and that appropriate reactions are taken based on the charge readings.

In one or more implementations, the open wire ratio computations can be performed on the secondary measurement pin voltages. Specifically, the open wire ratio is calculated by dividing the secondary measurement pin voltage when the open wire detection switch 502 is closed (referred to as “test voltage”) by the secondary measurement pin voltage when the open wire detection switch 502 is open (referred to as “baseline”). The baseline represents the normal operating scenario, and the test voltage is measured when the open wire detection switch 502 is closed to simulate the open wire condition.

In one or more implementations, baseline measurements are determined by evaluating the ratio of the secondary measurement pin test voltage to the secondary measurement pin baseline voltage. The baseline voltage for the secondary measurement pin can be measured when the open wire detection switch 502 is open, capturing the secondary measurement pin voltage at that point. When the open wire detection switch 502 is closed, a discharge occurs through the path, either in the form of voltage or current, altering the measured voltage. This altered value represents the secondary measurement pin test voltage. The open wire detection algorithm uses the ratio between the baseline voltage (measured with the open wire detection switch 502 open) and the test voltage (measured after the open wire detection switch 502 closes) for its calculations.

The resulting ratio for a single string (or cell) indicates whether the wire is truly open. In one or more implementations, if the ratio is less than a predetermined threshold (e.g., 0.7), it indicates a potential open wire condition. In one or more other implementations, if the ratio is greater than the predetermined threshold, then the wire is not considered open. In one or more implementations, the predetermined threshold can be a fixed value. In one or more other implementations, the predetermined threshold is a variable value.

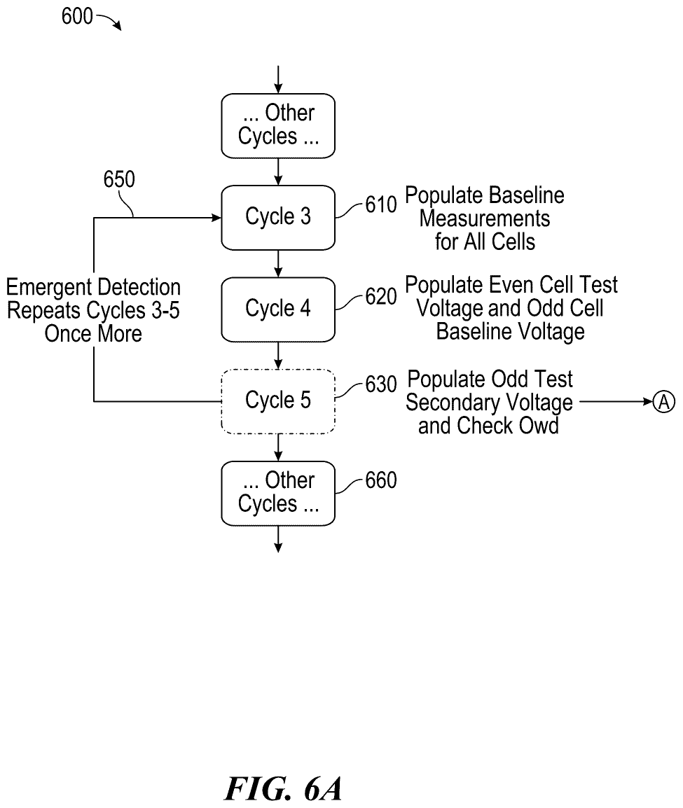

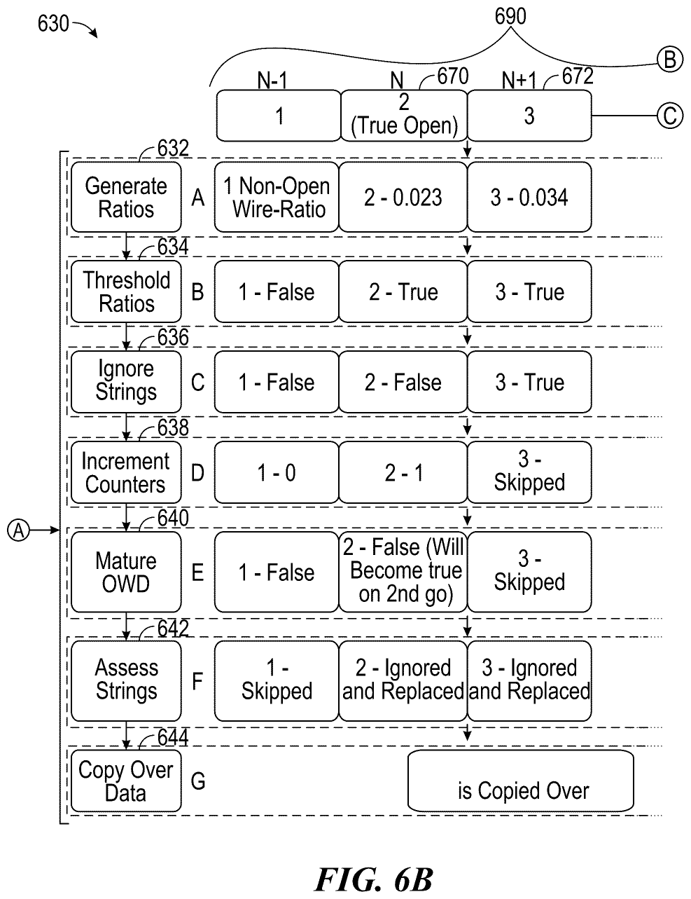

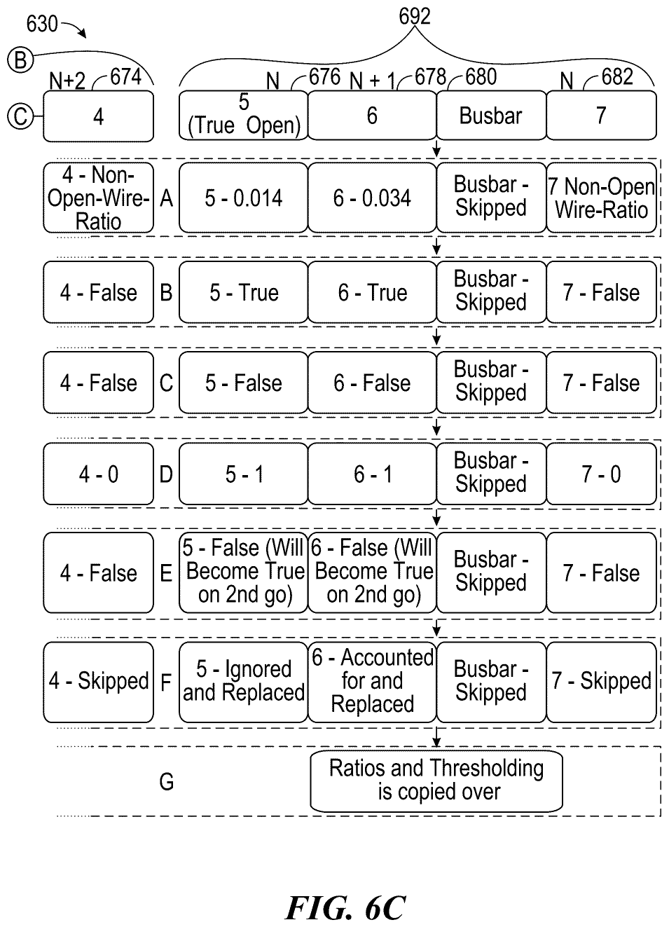

FIGS. 6A-6C illustrate block diagrams of an example process for open wire fault detection in accordance with one or more implementations of the subject technology. In one or more implementations, the battery management device 118 may execute a process 600 that includes seven cycles during which at least a portion of, or all, programmed measurements and diagnostics for the battery cells 120 may be conducted. These diagnostics may include reading cell voltages, reading cell temperatures, and detecting open wires. In one or more other implementations, other diagnostic checks may be performed, such as detecting clock drift and verifying whether the reference voltages to the voltage sensing circuit 402 are within range or out of range. The process 600 can be distributed across the seven cycles to facilitate comprehensive monitoring of the battery pack 110.

In cycle three (e.g., 610), cycle four (e.g., 620), and cycle five (e.g., 630), the detection of open wires can be specifically performed. In cycle three (e.g., 610), baseline measurements can be obtained with the open wire detection switch 502 of FIGS. 5A-5B being open (e.g., not conducting). In cycle four (e.g., 620) and cycle five (e.g., 630), test measurements can be obtained for even and odd cells, respectively. In one or more implementations, cells can be categorized as even or odd, where even cells can be labeled as 2, 4, 6, etc., and odd cells as 1, 3, 5, etc., for the battery monitoring circuitry 308 monitoring up to 16 cells. In one or more implementations, this categorization (and/or arrangement of labeled cells) may align with the ASIC architecture of the voltage sensing circuit 402, which may allow for flexibility in processing either all odd or all even cells together in separate cycles. Following cycle five (e.g., 630), the data can be processed to determine which of the 16 strings are open.

In one or more implementations, the subsequent cycles (e.g., cycles 6 and 7) can be used for additional diagnostics, such as temperature measurements, and the battery monitoring circuitry 308 can continuously loop through these cycles (e.g., 610, 620, 630) to maintain real-time monitoring. In one or more implementations, the complete sequence of all seven cycles (e.g., process 600) has a duration of about 800 milliseconds to complete. In one or more other implementations, cycle three (e.g., 610), cycle four (e.g., 620), and cycle five (e.g., 630) may be responsible for open wire detection, running about once every 800 milliseconds. In one or more implementations, the process 600 incorporates a de-bouncing mechanism to prevent false positives by confirming that an open wire is detected consistently before escalating to a necessary reaction. For example, for confirmation of an open wire fault detection, the battery monitoring circuit 308 may expect to see at least three consecutive positive open wire detections across cycles 3-5 (e.g., across 610, 620 and 630). Upon receiving indication of the three positive open wire detections, the wire is deemed truly open, and an appropriate reaction may be triggered (e.g., a transition of the battery pack 110 into a corresponding safe state level).

To facilitate accuracy of the open wire detection algorithm, the battery monitoring circuitry 308 can cycle through the detection process multiple times (cycles 3-5) to validate whether the over-voltage or under-voltage condition is due to an open wire or a genuine voltage issue. This looping process may be configurable, and the battery monitoring circuitry 308 may complete the verification within a predetermined timeframe. If a true over-voltage or under-voltage event is detected, the battery monitoring circuitry 308 in conjunction with the battery management device 114 can react within this timeframe to prevent potential battery thermal events. The decision-making process, whether the issue is a true open wire or an actual voltage fault, is configured to occur within this predetermined timeframe.

This timeframe can be programmable based at least in part on predefined safety requirements associated with the vehicle 100 and allows for the battery monitoring circuitry 308 to perform about three to four iterations, depending on the number of operations that fit within the predetermined timeframe. In one or more implementations, when the battery monitoring circuitry 308 detects a potential open wire condition in cycle five (e.g., 630), it proceeds through a feedback loop 650 and returns to cycle three (e.g., 610), bypassing cycle six (e.g., 660). The feedback loop 650 can repeat until the open wire detection is verified as a true open wire fault detection. After three consecutive detections in cycles three to five (e.g., 610-630), the battery monitoring circuitry 308 proceeds to cycle six (e.g., 660). This process can help distinguish between a false detection caused by an open wire and a true over-voltage or under-voltage event, as the reactions to each by the battery management device 114 can be distinct.

In one or more implementations, cycle three (e.g., 630) includes multiple operations to perform the open wire detection algorithm. For example, a first operation 632 includes generation of open wire ratio values that is based on the baseline voltage measurements and test voltage measurements. In another example, a second operation 634 includes a comparison of the open wire ratio values to a predetermined threshold (e.g., open wire detection threshold). In another example, a third operation 636 includes an operation to ignore strings (or cells) that are not considered to have potential open wire conditions. In another example, a fourth operation 638 includes incrementing a counter that tracks the number of instances of detecting a potential open wire condition for a corresponding string (or cell). In another example, a fifth operation 640 includes classifying the potential open wire condition for a corresponding string (or cell) as a mature open wire detection (or a true open wire fault detection). In another example, a sixth operation 642 includes assessing the strings (or cells) to see which can be skipped or replaced. In another example, a seventh operation 644 includes transferring data associated with the open wire fault detections to storage.

In one or more implementations, for a first scenario 690 where string two 670 (denoted as “N”) is truly open, the battery monitoring circuitry 308 transitions through the different operations (e.g., 632-644) under cycle five (e.g., 630). At the first operation 632, the battery monitoring circuitry 308 may compute open wire ratio values by comparing the baseline voltage values of a subject string to the test voltage values of that subject string, which are determined in cycle three (e.g., 610) and cycle four (e.g., 620), respectively. In one or more implementations, for strings that are not open (or do not have potential open wire conditions), the calculated open wire ratio values may be greater than a predetermined threshold (e.g., greater than 0.7). If a string is open (or has a potential open wire condition), such as string two 670 in this case, the open wire ratio value may not exceed the predetermined threshold (e.g., below 0.7). In one or more other implementations, if the open wire ratio value of an adjacent string (e.g., string three 672 also denoted as “N+1”) is also not greater than the predetermined threshold (e.g., does not exceed 0.7), the battery monitoring circuitry 308 may not rely solely on these two open wire ratio values to determine which string (e.g., string two 670 and/or string three 672) is truly open. In one or more implementations, if only the open wire ratio values of these two strings are considered, the open wire detection algorithm may incorrectly indicate that both string two 670 and string three 672 are open, implying a more severe condition with multiple open strings.

Embodiments of the subject technology address this challenge with an open wire detection algorithm configured to differentiate between a single open string and multiple open strings, as the system response may depend on the number of strings detected to have potential open wire conditions. By observing the impact on adjacent strings, the open wire detection algorithm can distinguish between actual open strings and strings affected by a neighboring open string. In one or more implementations, for a single string having a potential open wire condition, the system response may allow the user of the vehicle 100 (or driver) to continue driving the vehicle 100. In one or more other implementations, for multiple strings having potential open wire conditions, the system response may be more severe where the user of the vehicle 100 may not be allowed to resume driving the vehicle 100.

At the first operation 632, the battery monitoring circuit 308 generates the open wire ratio values for string two 670 (denoted as “N), string three 672 (denoted as “N+1) and string four 674 (denoted as “N+2). For example, the open wire ratio value of string two 670 is about 0.023 and the open wire ratio value of string three 672 is about 0.034. At the second operation 634, the open wire ratio value of string two 670 is compared against the predetermined threshold (e.g., 0.7) to see if it does not exceed the predetermined threshold. In this example, string two 670 is marked as true since its open wire ratio value does not exceed the predetermined threshold. Similarly, the open wire ratio value of string three 672 is compared against the predetermined threshold and marked as true as its open wire ratio value also does not exceed the predetermined threshold. In one or more other implementations, the open wire ratio value generated for string four 674 at the first operation 632 may be compared to the predetermined threshold at the second operation 634 In one example, string four 674 is marked as false at the second operation 634 as its open wire ratio value is determined to exceed the predetermined threshold. As illustrated in FIGS. 6B and 6C, string three 672 is adjacent to string two 670 and string four 674, and string four 674 is nonadjacent to string two 670.

In one or more implementations, the battery monitoring circuit 308 can ignore string three 672 temporarily because its open wire ratio value appears to be influenced by the potential open wire condition in string two 670. Due to physical wiring connections between adjacent strings (as described with reference to FIGS. 5A-5B), string three 672 may be impacted by the potential open wire condition in string two 670, so its open wire ratio value may be flagged at the third operation 636 to be ignored in the subsequent operations (e.g., operations 638-642). For example, each string in the battery pack 110 can have a positive and negative terminal, with adjacent strings sharing common wires. In this example, the negative terminal of string two 670 may connect to the positive terminal of string three 672. This process can be repeated a number of iterations (e.g., about three times) by the battery monitoring circuit 308, after which the battery monitoring circuit 308 can recheck string three 672 to confirm whether it is truly open. If string three 672 is later confirmed to be truly open, string three 672 may no longer be ignored by the battery monitoring circuit 308. Otherwise, string three 672 can remain ignored, and string two 670 becomes the only string identified as truly open. In one or more implementations, string four 674 may remain unaffected by the potential open wire condition in string two 670 because string four 674 is not physically connected (or directly connected) to string two 670. In this regard, string four 674 may not be temporarily ignored at the third operation 636 and instead remains available for the subsequent operations. The third operation 636 can prevent unnecessary responses to string three 672 when the true issue lies with string two 670.

At the fourth operation 638, a counter mechanism can be incremented after each open wire ratio value check. For string two 670, the counter mechanism associated with string two 670 can reach a count of three after at least three iterations through cycles 3-5 (e.g., 610-630), confirming that the potential open wire condition of string two 670 corresponds to a true open wire fault detection, while the counter mechanism associated with string three 673 can remain at a count of zero after the at least three iterations through cycles 3-5, indicating that string three 672 may not be flagged as truly open (e.g., the potential open wire condition of string three 672 does not correspond to a true open wire fault detection). For string four 674, the counter mechanism associated with string four 674 may remain at a count of zero after the at least three iterations through cycles 3-5, confirming that string four 674 is not truly open.

At the fifth operation 640, string two 670 is classified as a mature open wire detection (or a true open wire fault detection) after the counter mechanism associated with string two 670 reaches the maximum count for confirmation. For string three 672 and string four 674, these two strings do not reach maturity to be classified as true open wire fault detections since their respective counts remained at zero. At the sixth operation 642, string two 670 and string three 672 may be ignored and replaced after each iteration, while string four 674 is skipped for assessment. At the seventh operation 644, the open wire ratio values of each string (e.g., 670-674) can be copied to storage (e.g., memory 306).

In one or more implementations, for a second scenario 692 where a busbar 680 is located between two strings (e.g., string six 678 (denoted as “N+1”) and string seven 682 (denoted as “N”)) in the battery pack 110, the busbar 680 may serve as a resistive physical connection between multiple cells. The placement of the busbar 680, which can separate the positive terminal of string six 678 and the negative terminal of string seven 682, results in these terminals not being at the same physical location (as described with reference to FIGS. 5A-5B). In one or more implementations, the busbar 680 may introduce micro-resistance between cell connections. This resistance may be factored into the detection process performed by the battery monitoring circuit 308, particularly when dealing with adjacent string connections such as string six 678 and string seven 682. Depending on the physical configuration, the battery monitoring circuit 308 can evaluate whether voltage fluctuations between these strings result from true open wire conditions or from external factors such as shared resistive elements. This configuration of the busbar 680 can affect string six 678, such that if string five 676 (denoted as “N”) is truly open, the open wire ratio value for string six 678 can be impacted. In one or more implementations, it may not be possible to rely on the open wire ratio value of string seven 682 to determine if string six 678 is truly open because the terminals between string six 678 and string seven 682 are not physically connected. In one or more other implementations, this can introduce a limitation in detecting whether string six 678 is truly open or merely influenced by the condition of string five 676. For example, the busbar 680 presence may prevent the N+2 check from fully validating the open wire detection algorithm.

In one or more implementations, in the second scenario 692, the battery monitoring circuit 308 may conservatively conclude that string six 678 is truly open. This limitation may affect only one string across the battery pack 110 where the busbar 680 is located adjacently, reducing the probability of occurrence. If the limitation occurs involving multiple strings having potential open wire conditions, the battery monitoring circuit 308 may already be operating under a multiple-cell open wire detection scenario, and the system reaction may remain the same.

In one or more other implementations, the battery monitoring circuit 308 may perform the open wire detection algorithm while considering the absence of an N+2 cell when N approaches the total number of battery cells (e.g., battery cells 120 of FIG. 1A). In one or more implementations, with 16 cells in the battery pack 110, when N equals 15, there may not be an N+2 cell available. For these conditions, the battery monitoring circuit 308 may adjust the open wire detection algorithm by processing the cells individually. For N equal to 15, the battery monitoring circuit 308 may employ a method to detect open wires without relying on an N+2 cell. In detecting an open wire in string 16, the open wire detection algorithm may not perform the N+2 check due to the absence of a 17th cell. In one or more implementations, the process during cycle five (e.g., 630) may include a loop that iterates from string 1 through string 14, and for strings 15 and 16, the battery monitoring circuit 308 can conduct individual checks without referencing a string N+2. In one or more other implementations, for N equal to 16, the last cell may be connected to the supply voltage, and its behavior when truly open can differ from other cells. For example, if string 16 is truly open, unusual behavior may occur across the battery pack 110, such as all strings appearing to have open wires. Because the 16th cell may be configured to power the voltage sensing circuit 402 itself; therefore, if it has an open wire, the voltage sensing circuit 402 may not be powered, and measurements may not be performed. This condition can be detected by the ECU 302, as it will be unable to communicate with the voltage sensing circuit 402.

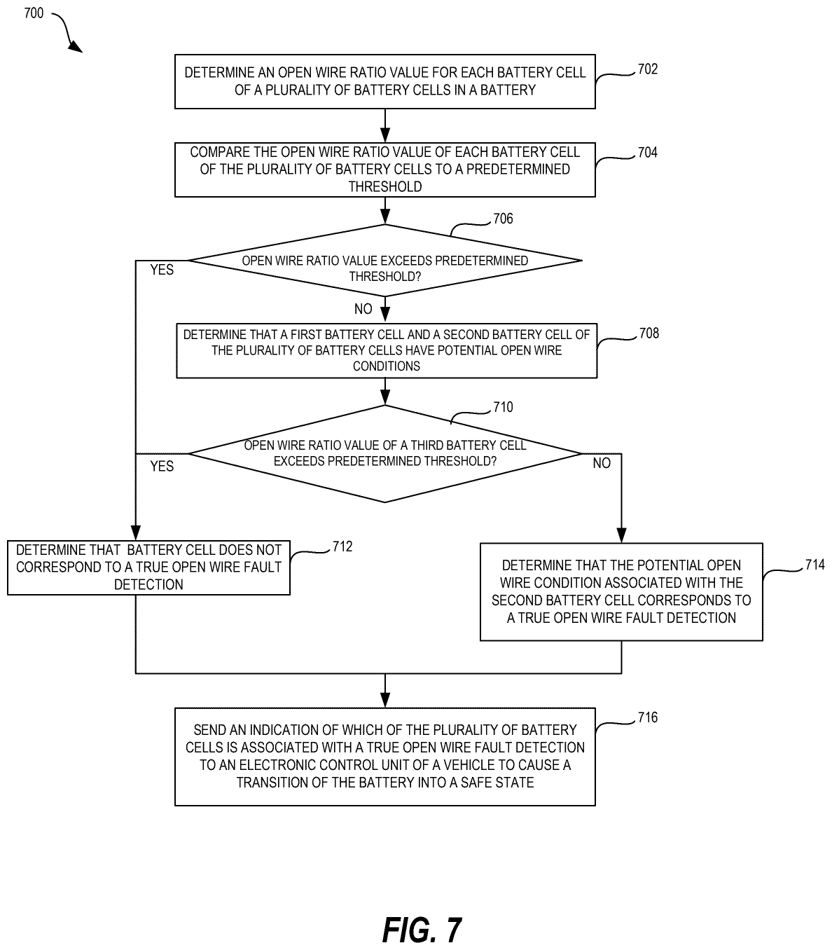

FIG. 7 illustrates a flow diagram of an example process 700 for performing open wire fault detection in accordance with one or more implementations of the subject technology. For explanatory purposes, the process 700 is primarily described herein with reference to the vehicle 100 of FIGS. 1A-B, and/or various components thereof. However, the process 700 is not limited to the vehicle 100 of FIGS. 1A-B, and one or more steps (or operations) of the process 700 may be performed by one or more other structural components of the vehicle 100 and/or of other suitable moveable apparatuses, devices, or systems. Further, for explanatory purposes, some of the steps of the process 700 are described herein as occurring in serial, or linearly. However, multiple steps of the process 700 may occur in parallel. In addition, the steps of the process 700 need not be performed in the order shown and/or one or more steps of the process 700 need not be performed and/or can be replaced by other operations.

At step 702, the battery monitoring circuit 308 may determine an open wire ratio value for each battery cell of a plurality of battery cells in a battery.

At step 704, the battery management circuit 308 may compare the open wire ratio value of each battery cell of the plurality of battery cells to a predetermined threshold.

At 706, the battery management circuit 308 may determine whether the open wire ratio value of each of a first battery cell of the plurality of battery cells and a second battery cell of the plurality of battery cells exceeds the predetermined threshold. In one or more implementations, the open wire ratio value not exceeding the predetermined threshold indicates a potential open wire condition. If the open wire ratio value exceeds the predetermined threshold, the process 700 proceeds to step 712. Otherwise, the process 700 proceeds to step 708.

At step 708, the battery monitoring circuit 308 may determine that a first battery cell and a second battery cell of the plurality of battery cells have potential open wire conditions.

At step 710, the battery monitoring circuit 308 may compare the open wire ratio value of a third battery cell of the plurality of battery cells to the predetermined threshold. If the open wire ratio value exceeds the predetermined threshold, the process 700 proceeds to step 712. Otherwise, the process 700 proceeds to step 714.

At 712, the battery monitoring circuit 308 may determine that the battery cell does not correspond to a true open wire fault detection based on either the determination that the open wire ratio value of the battery cell itself does exceed the predetermined threshold or that the open wire ratio value of an adjacent cell (e.g., the third battery cell) does exceed the predetermined threshold.

At 714, the battery monitoring circuit 308 may determine that the potential open wire condition associated with the second battery cell corresponds to a true open wire fault detection based on the determination that the open wire ratio value of the third battery cell exceeds the predetermined threshold.

At 716, the battery monitoring circuit 308 may send an indication of which of the plurality of battery cells is associated with a true open wire fault detection to the ECU to cause a transition of the battery into a safe state.

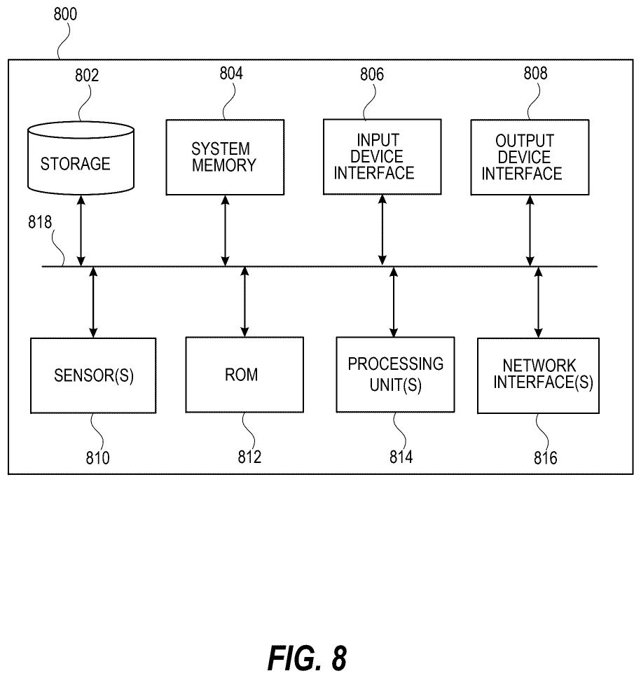

FIG. 8 illustrates an example electronic system 800 with which aspects of the present disclosure may be implemented. The electronic system 800 can be, and/or can be a part of, any electronic device for providing the features and performing processes described in reference to FIGS. 1-7, including but not limited to a vehicle, computer, server, smartphone, and wearable device. The electronic system 800 may include various types of computer-readable media and interfaces for various other types of computer-readable media. The electronic system 800 includes a persistent storage device 802, system memory 804 (and/or buffer), input device interface 806, output device interface 808, sensor(s) 810, ROM 812, processing unit(s) 814, network interface 816, bus 818, and/or subsets and variations thereof.

The bus 818 collectively represents all system, peripheral, and chipset buses that communicatively connect the numerous internal devices and/or components of the electronic system 800, such as any of the components of the vehicle 100 discussed above with respect to FIG. 4. In one or more implementations, the bus 818 communicatively connects the one or more processing unit(s) 814 with the ROM 812, the system memory 804, and the persistent storage device 802. From these various memory units, the one or more processing unit(s) 814 retrieves instructions to execute and data to process in order to execute the processes of the subject disclosure. The one or more processing unit(s) 814 can be a single processor or a multi-core processor in different implementations. In one or more implementations, one or more of the processing unit(s) 814 may be included on an ECU 204, such as in the form of the processor 206.

The ROM 812 stores static data and instructions that are needed by the one or more processing unit(s) 814 and other modules of the electronic system 800. The persistent storage device 802, on the other hand, may be a read-and-write memory device. The persistent storage device 802 may be a non-volatile memory unit that stores instructions and data even when the electronic system 800 is off. In one or more implementations, a mass-storage device (such as a magnetic or optical disk and its corresponding disk drive) may be used as the persistent storage device 802.

In one or more implementations, a removable storage device (such as a flash drive and its corresponding solid state device) may be used as the persistent storage device 802. Like the persistent storage device 802, the system memory 804 may be a read-and-write memory device. However, unlike the persistent storage device 802, the system memory 804 may be a volatile read-and-write memory, such as RAM. The system memory 804 may store any of the instructions and data that one or more processing unit(s) 814 may need at runtime. In one or more implementations, the processes of the subject disclosure are stored in the system memory 804, the persistent storage device 802, and/or the ROM 812. From these various memory units, the one or more processing unit(s) 814 retrieves instructions to execute and data to process in order to execute the processes of one or more implementations.

The persistent storage device 802 and/or the system memory 804 may include one or more machine learning models. Machine learning models, such as those described herein, are often used to form predictions, solve problems, recognize objects in image data, and the like. For example, machine learning models described herein may be used to predict the thermal demands of a vehicle battery pack along a certain part of a route of the vehicle. Various implementations of the machine learning model are possible. For example, the machine learning model may be a deep learning network, a transformer-based model (or other attention-based models), a multi-layer perceptron or other feed-forward networks, neural networks, and the like. In various examples, machine learning models may be more adaptable as machine learning models may be improved over time by re-training the models as additional data becomes available.

The bus 818 also connects to the input device interfaces 806 and output device interfaces 808. The input device interface 806 enables a user to communicate information and select commands to the electronic system 800. Input devices that may be used with the input device interface 806 may include, for example, alphanumeric keyboards, touch screens, and pointing devices. The output device interface 808 may enable the electronic system 800 to communicate information to users. For example, the output device interface 808 may provide the display of images generated by electronic system 800. Output devices that may be used with the output device interface 808 may include, for example, printers and display devices, such as a liquid crystal display (LCD), a light emitting diode (LED) display, an organic light emitting diode (OLED) display, a flexible display, a flat panel display, a solid state display, a projector, or any other device for outputting information.

One or more implementations may include devices that function as both input and output devices, such as a touchscreen. In these implementations, feedback provided to the user can be any form of sensory feedback, such as visual feedback, auditory feedback, or tactile feedback; and input from the user can be received in any form, including acoustic, speech, or tactile input.

The bus 818 also connects to sensor(s) 810. The sensor(s) 810 may include a location sensor, which may be used in determining device position based on positioning technology. For example, the location sensor may provide for one or more of GNSS positioning, wireless access point positioning, cellular phone signal positioning, Bluetooth signal positioning, image recognition positioning, and/or an inertial navigation system (e.g., via motion sensors such as an accelerometer and/or gyroscope). In one or more implementations, the sensor(s) 810 may be utilized to detect movement, travel, and orientation of the electronic system 800. For example, the sensor(s) may include an accelerometer, a rate gyroscope, and/or other motion-based sensor(s). The sensor(s) 810 may include one or more biometric sensors and/or image sensors for authenticating a user.

The bus 818 also couples the electronic system 800 to one or more networks and/or to one or more network nodes through the one or more network interface(s) 816. In this manner, the electronic system 800 can be a part of a network of computers (such as a local area network or a wide area network). Any or all components of the electronic system 800 can be used in conjunction with the subject disclosure.

Implementations within the scope of the present disclosure can be partially or entirely realized using a tangible computer-readable storage medium (or multiple tangible computer-readable storage media of one or more types) encoding one or more instructions. The tangible computer-readable storage medium also can be non-transitory in nature.

The computer-readable storage medium can be any storage medium that can be read, written, or otherwise accessed by a general purpose or special purpose computing device, including any processing electronics and/or processing circuitry capable of executing instructions. For example, without limitation, the computer-readable medium can include any volatile semiconductor memory, such as RAM, DRAM, SRAM, T-RAM, Z-RAM, and TTRAM. The computer-readable medium also can include any non-volatile semiconductor memory, such as ROM, PROM, EPROM, EEPROM, NVRAM, flash, nvSRAM, FeRAM, FeTRAM, MRAM, PRAM, CBRAM, SONOS, RRAM, NRAM, racetrack memory, FJG, and Millipede memory.

Further, the computer-readable storage medium can include any non-semiconductor memory, such as optical disk storage, magnetic disk storage, magnetic tape, other magnetic storage devices, or any other medium capable of storing one or more instructions. In one or more implementations, the tangible computer-readable storage medium can be directly coupled to a computing device, while in other implementations, the tangible computer-readable storage medium can be indirectly coupled to a computing device, e.g., via one or more wired connections, one or more wireless connections, or any combination thereof.

Instructions can be directly executable or can be used to develop executable instructions. For example, instructions can be realized as executable or non-executable machine code or as instructions in a high-level language that can be compiled to produce executable or non-executable machine code. Further, instructions also can be realized as or can include data. Computer-executable instructions also can be organized in any format, including routines, subroutines, programs, data structures, objects, modules, applications, applets, functions, etc. As recognized by those of skill in the art, details including, but not limited to, the number, structure, sequence, and organization of instructions can vary significantly without varying the underlying logic, function, processing, and output.

While the above discussion primarily refers to microprocessor or multi-core processors that execute software, one or more implementations are performed by one or more integrated circuits, such as ASICs or FPGAs. In one or more implementations, such integrated circuits execute instructions that are stored on the circuit itself.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the present disclosure. The word exemplary is used to mean serving as an example or illustration. To the extent that the term includes, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different orders. Some of the steps, operations, or processes may be performed simultaneously. The accompanying method claims, if any, present elements of the various steps, operations, or processes in a sample order, and are not meant to be limited to the specific order or hierarchy presented. These may be performed in serial, linearly, in parallel, or in different order. It should be understood that the described instructions, operations, and systems can generally be integrated together in a single software/hardware product or packaged into multiple software/hardware products.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S. C. § 112(f), unless the element is expressly recited using the phrase “means for” or, in the case of a method claim, the element is recited using the phrase “step for.”

Those of skill in the art would appreciate that the various illustrative blocks, modules, elements, components, methods, and algorithms described herein may be implemented as hardware, electronic hardware, computer software, or combinations thereof. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The title, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A system comprising:
an electronic control unit (ECU); and
a battery monitoring circuit configured to:
determine an open wire ratio value for each battery cell of a plurality of battery cells in a battery;
determine that a first battery cell and a second battery cell of the plurality of battery cells have potential open wire conditions based on a comparison between the open wire ratio value of each of the first battery cell and the second battery cell and a predetermined threshold, wherein the open wire ratio value not exceeding the predetermined threshold indicates a potential open wire condition;
determine whether the potential open wire condition associated with the second battery cell corresponds to a true open wire fault detection based on a comparison between the open wire ratio value of a third battery cell of the plurality of battery cells and the predetermined threshold; and
send an indication of which of the plurality of battery cells is associated with a true open wire fault detection to the ECU to cause a transition of the battery into a safe state.

2. The system of claim 1, wherein the battery monitoring circuit is further configured to determine that the second battery cell has a true open wire condition based on the open wire ratio value of the third battery cell not exceeding the predetermined threshold.

3. The system of claim 1, wherein the battery monitoring circuit is further configured to determine that the second battery cell does not have a true open wire condition based on the open wire ratio value of the third battery cell exceeding the predetermined threshold.

4. The system of claim 1, wherein the third battery cell is adjacent to the second battery cell and nonadjacent to the first battery cell.

5. The system of claim 1, wherein the open wire ratio value is a ratio of a test voltage associated with a battery cell of the plurality of battery cells to a baseline voltage associated with the battery cell.

6. The system of claim 5, wherein the battery monitoring circuit is further configured to obtain a measurement of the test voltage based on an open wire detection switch configured as closed, and the battery monitoring circuit is further configured to obtain a measurement of the baseline voltage based on the open wire detection switch configured as open.

7. The system of claim 1, wherein the battery monitoring circuit is further configured to increment a counter associated with a battery cell of the plurality of battery cells in response to a determination of the battery cell having a true open wire condition.

8. The system of claim 7, wherein the battery monitoring circuit is further configured to determine a confirmation that the second battery cell has a true open wire condition after a plurality of iterations of comparing the open wire ratio value of each of the second battery cell and the third battery cell to the predetermined threshold.

9. The system of claim 1, wherein the battery monitoring circuit is further configured to determine that the second battery cell has a true open wire condition based on the open wire ratio value of the second battery cell exceeding the predetermined threshold and the third battery cell is nonadjacent to the second battery cell.

10. The system of claim 9, wherein a busbar is located between the second battery cell and the third battery cell.

11. The system of claim 1, wherein each battery cell in the plurality of battery cells is interconnected in series, and wherein the open wire ratio value of the third battery cell is determined sequentially after determining the open wire ratio value of the second battery cell.

12. The system of claim 1, wherein the battery monitoring circuit is further configured to cause the battery to transition between different safe state levels based on a number of battery cells in the plurality of battery cells determined to have a true open wire condition.

13. A method of managing a vehicle, the method comprising:
determining an open wire ratio value for each battery cell of a plurality of battery cells in a battery;
comparing the open wire ratio value of each battery cell of the plurality of battery cells to a predetermined threshold, wherein a first battery cell and a second battery cell of the plurality of battery cells have respective open wire ratio values that do not exceed the predetermined threshold;
determining whether the second battery cell has a true open wire condition based on a comparison between the open wire ratio value of a third battery cell of the plurality of battery cells and the predetermined threshold; and
sending, to an electronic control unit of a vehicle, an indication of whether one or more battery cells of the plurality of battery cells is associated with an open wire fault detection to cause a transition of the battery into a safe state.

14. The method of claim 13, further comprising determining that the second battery cell has a true open wire condition based on the open wire ratio value of the third battery cell not exceeding the predetermined threshold.

15. The method of claim 13, further comprising determining that the second battery cell does not have a true open wire condition based on the open wire ratio value of the third battery cell exceeding the predetermined threshold.

16. The method of claim 13, further comprising:
obtaining a measurement of a test voltage associated with a battery cell of the plurality of battery cells based on an open wire detection switch configured as closed; and
obtaining a measurement of a baseline voltage associated with the battery cell based on the open wire detection switch configured as open.

17. The method of claim 13, further comprising incrementing a counter associated with a battery cell of the plurality of battery cells in response to a determination of the battery cell having a true open wire condition.

18. The method of claim 13, further comprising determining a confirmation that the second battery cell has a true open wire condition after a plurality of iterations of comparing the open wire ratio value of each of the second battery cell and the third battery cell to the predetermined threshold.

19. The method of claim 13, further comprising determining that the second battery cell has a true open wire condition based on the open wire ratio value of the second battery cell exceeding the predetermined threshold and the third battery cell is nonadjacent to the second battery cell.

20. A vehicle, comprising:
one or more sensors;
an electronic control unit (ECU); and
a battery monitoring circuit configured to:
determine an open wire ratio value for each battery cell of a plurality of battery cells in a battery;
determine that a first battery cell and a second battery cell of the plurality of battery cells have potential open wire conditions based on the open wire ratio value of each of the first battery cell and the second battery cell not exceeding a predetermined threshold;
compare the open wire ratio value of a third battery cell of the plurality of battery cells to the predetermined threshold to determine whether the second battery cell has a true open wire condition; and
send an indication of an open wire fault detection associated with one or more battery cells of the plurality of battery cells to the ECU to cause a transition of the battery into a safe state.
